(19) United States
(12) Patent Application Publication
(10) Pub. No.: US 2011/0241051 A1
(43) Pub. Date: Oct. 6, 2011

(54) Organic Electroluminescent Device

(75) Inventors: Julian Carter, Cambridgeshire (GB); Shunpu Li, Cork (IE)

(73) Assignee: Cambridge Display Technology Limited, Cambridgeshire (GB)

(21) Appl. No.: 13/121,375

(22) PCT Filed: Sep. 25, 2009
(86) PCT No.: PCT/GB2009/002285

§ 371 Date: Jun. 20, 2011

(30) Foreign Application Priority Data
Oct. 2, 2008 (GB) 0818058.0

(51) Int. Cl. H01L 33/58; B29D 11/00; G02B 5/18

(52) U.S. Cl. 257/98; 438/32; 264/1.1; 264/2.1; 359/569; 359/576; 257/E33.06

(57) ABSTRACT

An organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode, the second electrode being transparent to light emitted by the light emitting layer; and a transparent encapsulant disposed over the second electrode, wherein the transparent encapsulant comprises a microlens array formed by a top surface of the transparent encapsulant and a diffraction grating formed by a bottom surface of the transparent encapsulant.

### FIELD OF THE INVENTION

The present invention relates to an organic electroluminescent device and a method of manufacture thereof.

### BACKGROUND OF THE INVENTION

Organic electroluminescent devices are known, for example, from PCT/WO/13148 and U.S. Pat. No. 4,539,507. Examples of such devices are shown in FIGS. 1 and 2. Such devices generally comprise: a substrate 2; a first electrode 4 disposed over the substrate 2 for injecting charge of a first polarity; a second electrode 6 disposed over the first electrode 4 for injecting charge of a second polarity opposite to said first polarity; an organic light emitting layer 8 disposed between the first and the second electrodes; and an encapsulant 10 disposed over the second electrode 6. In one arrangement shown in FIG. 1, the substrate 2 and first electrode 4 are transparent to allow light emitted by the organic light-emitting layer 8 to pass therethrough. In another arrangement shown in FIG. 2, the second electrode 6 and the encapsulant 10 are transparent so as to allow light emitted from the organic light-emitting layer 8 to pass therethrough.

Variations of the above described structures are known. The first electrode may be the anode and the second electrode may be the cathode. Alternatively, the first electrode may be the cathode and the second electrode may be the anode. Further layers may be provided between the electrodes and the organic light-emitting layer in order to aid charge injection and transport. The organic material in the light-emitting layer may comprise a small molecule, a dendrimer or a polymer and may comprise phosphorescent moieties and/or fluorescent moieties. The light-emitting layer may comprise a blend of materials including light emitting moieties, electron transport moieties and hole transport moieties. These may be provided in a single molecule or in separate molecules.

By providing an array of devices of the type described above, a display may be formed comprising a plurality of emitting pixels. The pixels may be of the same type to form a monochrome display or they may be different colours to form a multicolour display.

A problem with organic electroluminescent devices is that much of the light emitted by organic light-emitting material in the organic light-emitting layer does not escape from the device. The light may be lost within the device by scattering, internal reflection, wave guiding, absorption and the like. For example, it will be understood that light is emitted from the electroluminescent layer over a range of angles relative to the plane of the device. Light hitting an interface in the device at a shallow angle can be internally reflected.

One way of increasing the amount of light which escapes from the device is to provide an optical structure in the device which reduces one or more of scattering, internal reflection, wave guiding, absorption and the like. Such an optical structure may, for example, comprise a microlens array.

An earlier application of the present applicant, published as GB2421626, discloses forming a microlens array in a thin film encapsulant of an organic electroluminescent device by depositing the layers of the electroluminescent device, depositing a thin layer encapsulant over the device layers, and providing an optical structure in the encapsulant by, for example, embossing a microlens array therein. Such an arrangement provides a so called top-emitting device structure with an optical structure to increase light output from a top side of the device. Such an arrangement is illustrated in FIG. 3 comprising: a substrate 2; a first electrode 4 disposed over the substrate 2 for injecting charge of a first polarity; a second electrode 6 disposed over the first electrode 4 for injecting charge of a second polarity opposite to the first polarity; an organic light emitting layer 8 disposed between the first and the second electrode; and a thin film encapsulant 10 disposed over the second electrode 6, wherein the second electrode 6 is transparent to light emitted by the light emitting layer 8 and a microlens array 12 is provided in the thin film encapsulant 10.

One possible problem with the aforementioned arrangement is that forming an optical structure in the thin film encapsulant by, for example, embossing can damage underlying layers of the device. Another problem with the aforementioned arrangement is that there is still a significant amount of light lost at the interface between the top electrode of the organic electroluminescent device and the bottom surface of the encapsulant.

Optical structures other than microlens arrays are known in the art for increasing the amount of light which escapes from the device. Examples of such structures include diffraction gratings and optical cavities. However, one problem with such structures is that they tend to increase angular variations in colour.

It is an aim of the present invention is to address one or more of the aforementioned problems.

### SUMMARY OF THE INVENTION

The present applicant has found that the angular colour variation induced by optical structures such as diffraction gratings can be reduced by combining such optical structures with an overlying microlens array. The microlens array tends to average perceived light over space and wavelength thus reducing angular colour variations. As such, the microlens array and the diffraction grating (or other optical structure which increases angular colour variations) act in a complementary manner.

Further still, the present applicant has realized that light loss may be further reduced when compared with the previously discussed arrangements by combining the features of a microlens array and an optical structure such as a diffraction grating. In particular, if a microlens array is provided in an outer surface of the encapsulant as described in GB2421626, light lost at the interface between the top electrode of the organic electroluminescent device and the bottom surface of the encapsulant can be reduced by introducing another optical structure such as a diffraction grating on the bottom surface of the encapsulant. Furthermore, it has been found that such a grating can be introduced without undue increase in angular colour variations due to the complementary effect of the microlens array.

Further still, the present applicant has realized that an encapsulant film can be pre-fabricated with a microlens array on one side and another optical structure such as a diffraction grating on the other side in order to form a double side structured optical foil. Such a pre-fabricated encapsulant film can then be applied to the top surface of an organic electroluminescent device without requiring any further processing steps to form optical structures after application of the encapsulant film to the device. Thus, damage of underlying layers by, for example, embossing, is avoided.

In light of the above, and in accordance with a first aspect of the invention, there is provided an organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode, the second electrode being transparent to light emitted by the light emitting layer; and a transparent encapsulant disposed over the second electrode, wherein the transparent encapsulant comprises a microlens array formed by a top surface of the transparent encapsulant and an optical structure formed by a bottom surface of the transparent encapsulant. The optical structure formed by the bottom surface of the transparent encapsulant is preferably a diffractive structure such as a diffraction grating.

The transparent encapsulant may be disposed directly on the second electrode or directly on a thin film encapsulant disposed over the second electrode. With such an arrangement, the optical structures are located closer to the organic light emitting layer than, for example, if the optical structures are formed in an encapsulant spaced apart from the second electrode by a cavity. This is desirable because optical structures can cause undesirable optical side effects. For example, as viewing angle changes undesirable optical effects can be introduced by the presence of the optical structures resulting in, for example, variation in brightness with viewing angle. These optical side effects are dependent on the distance of the optical structure from the light emitting layer. By providing the optical structure close to the light emitting layer, optical side effects are reduced while still increasing light output from the device.

In one arrangement, the encapsulant film is formed of a single layer of material such as a plastic film. The encapsulant film may comprise an elastomer such as PDMS (polymethylsiloxane). Alternatively a bilayer or trilayer structure can be provided.

The encapsulant film may comprise a bulk material in which the optical structure is disposed and a coating material. The coating material can be disposed on either or both of top and bottom sides of the bulk material. The coating material may be selected for better refractive index matching at the interfaces located at the top and bottom of the encapsulant film. Alternatively, the coating material coats the optical structure and is selected to increase the difference in refractive index between structural elements of the optical structure to increase the effectiveness of the optical structure. An example of such a coating material is an inorganic material such as SiN. The bulk material may be provided by the previously mentioned elastomer.

A further glass or transparent plastic encapsulant can be provided over the encapsulant film. The glass or transparent plastic encapsulant may comprise a recess which can receive one or more underlying layers of the device. Most preferably, the glass or transparent plastic encapsulant comprises a recess with side walls disposed around the periphery of the device and bonded to the substrate to form a seal using, for example, a line of adhesive around the periphery of the device. The side walls serve to encapsulate the sides of the device against ingress of moisture and oxygen while also spacing the encapsulant by a suitable distance above the second electrode to prevent damage of the device when the encapsulant is applied.

Preferably the first electrode is an anode and the second electrode is a cathode. The cathode may comprise a layer of barium with a layer of aluminium thereover. Each of these layers is preferably less than 10 nm thick and more preferably each layer is approximately 5 nm thick. This arrangement provides a cathode with good electrical properties while also being transparent. Furthermore, the cathode does not adversely react with other components in the device. An alternative cathode utilizes a layer of barium with a layer of silver thereover. Each of these layers is preferably less than 10 nm thick and more preferably each layer is approximately 5 nm thick. This cathode is more transparent than the aforementioned Barium/Aluminium arrangement.

In one arrangement the substrate, the first electrode and the second electrode are transparent to light emitted by the organic light emitting layer. This arrangement, combined with a transparent encapsulant results in a fully transparent device architecture.

According to a second aspect of the present invention there is provided a method of manufacturing an organic electroluminescent device comprising the steps: depositing a first electrode over a substrate for injecting a charge of a first polarity; depositing an organic light emitting layer over the first electrode; depositing a second electrode over the organic light emitting layer for injecting charge of a second polarity opposite to said first polarity, the second electrode being transparent to light emitted by the light emitting layer; and providing a transparent encapsulant over the second electrode, wherein the transparent encapsulant has a microlens array disposed in a top surface of the transparent encapsulant and another optical structure formed by the bottom surface of the transparent encapsulant.

Preferably, the microlens array and the other optical structure are formed in the transparent encapsulant prior to disposing the thin film encapsulant over the second electrode. Such a method allows the microlens array and the other optical structure to be formed without damaging active layers of the organic electroluminescent device.

Preferably the microlens array and the other optical structure are provided by embossing, printing, etching, photolithographic patterning, roll-to-roll processing or the like.

If the optical structure is embossed, the encapsulant film may be softened by heating or the application of a solvent for embossing the microlens array and the other optical structure therein. Alternatively, a precursor material may be deposited as a coating on the encapsulant film and an embossing mould applied prior to curing of the precursor material to form the microlens array and/or the other optical structure. As an alternative to the embossing mould, the microlens array and/or the other optical structure may be embossed using a pair of opposing rollers each having a patterned surface corresponding respectively to the microlens array and the other optical structure. The encapsulant film is passed between the rollers which roll along opposing sides of the encapsulant film to form the microlens array and the other optical structure.

According to a third aspect of the present invention there is provided an encapsulant film for encapsulating an organic electroluminescent device as previously described. According to a fourth aspect of the present invention there is provided a method of making such an encapsulant film.

### BRIEF DESCRIPTION OF THE DRAWINGS

Embodiments of the present invention will now be described by way of example only with reference to the accompanying drawings, in which:—

FIG. 1 shows a known structure of a bottom-emitting organic light emitting device;

FIG. 2 shows a known structure of a top-emitting organic light emitting device;

FIG. 3 shows a known structure of a top-emitting organic light emitting device with an optical structure in a thin film encapsulant disposed over the device;

FIG. 4 shows a top-emitting organic light emitting device in accordance with an embodiment of the present invention;

FIGS. 5(a) to 5(f) show the steps involved in forming a top-emitting organic light emitting device in accordance with an embodiment of the present invention; and

FIGS. 6(a) and 6(b) show two methods of forming an encapsulant film using rollers.

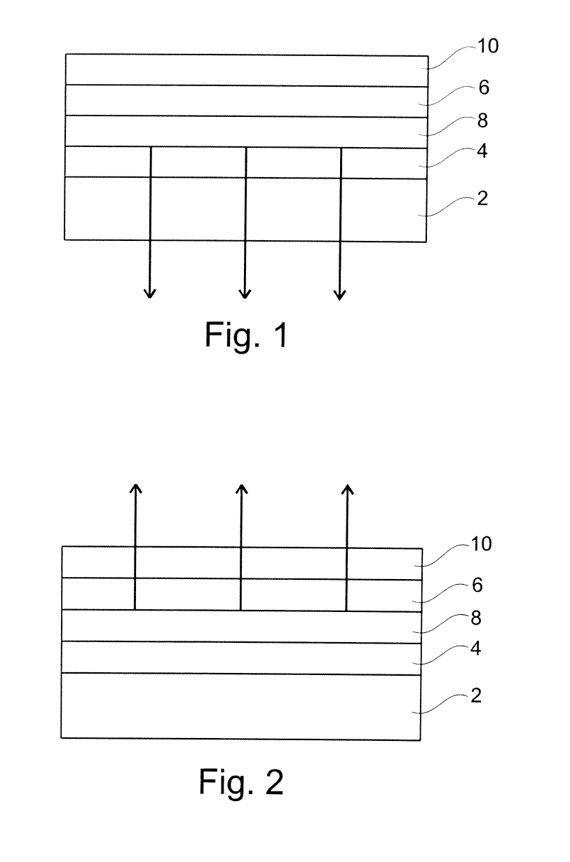

### DETAILED DESCRIPTION OF EMBODIMENTS OF THE PRESENT INVENTION

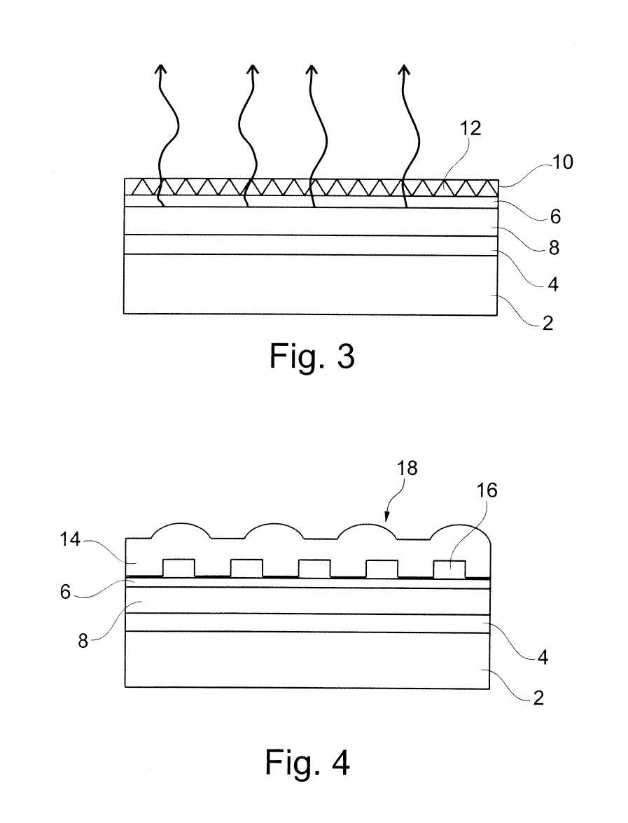

FIG. 4 shows a top-emitting organic light emitting device in accordance with an embodiment of the present invention. The structure of the device is similar in many respects to the prior art arrangement illustrated in FIG. 3 and like reference numerals have been used for like parts. As in the arrangement of FIG. 3, the device comprises: a substrate 2; a first electrode 4 disposed over the substrate 2 for injecting charge of a first polarity; a second electrode 6 disposed over the first electrode 4 for injecting charge of a second polarity opposite to the first polarity; and an organic light emitting layer 8 disposed between the first and the second electrode. The difference between the arrangement illustrated in FIG. 4 and that illustrated in FIG. 3 lies in the provision of a double side structured encapsulant film 14 rather than a single side structured encapsulant film 10. The double side structured encapsulant film 14 comprises an optical structure 16 (in this case a diffraction grating) on a lower side thereof and a microlens array 18 on an upper side thereof. The optical structure 16 enhances light extraction from functional layers of devices. The microlens array 18 further enhances light extraction to the external environment while reducing angular colour variations caused by the optical structure 16.

The diffraction grating may comprise projections having a width typically in the range 300 nm˜2 μm. The microlenses typical have a width in the range 300 nm˜50 μm.

Preferably, the light emitting layer 8 comprises pixels which are larger in surface area than the microlenses such that a plurality of microlenses are disposed over each pixel. For example, 2 to 100 microlenses may be provided for each pixel. Clearly, the larger the pixels the more easy it will be to provide a large number of microlenses for each pixel. Providing a large number of microlenses for each pixel can reduce undesirable optical side effects.

The diffraction grating illustrated in FIG. 4 comprises a plurality of protrusions with voids disposed therebetween. The voids may be filled with air or an inert gas. Alternatively another material may be provided in the voids in order to tune the diffraction grating according to a particular use. The effectiveness of the grating will depend on the difference in refractive index of the voids and the protrusions as well as the size of the protrusions and voids relative to the wavelength of emitted light.

The encapsulant film may comprise a bulk material and a coating material. The coating material may be selected to coat the optical structure and tune its performance. The coating material may be provided on one or both sides of the bulk material. For example, the coating material may be selected according to its refractive index in order to provide a large difference in refractive index between the protrusions and voids in a diffraction grating thus increasing the effectiveness of the grating. A suitable material for the coating is, for example, SiN although a range of possible materials could be used.

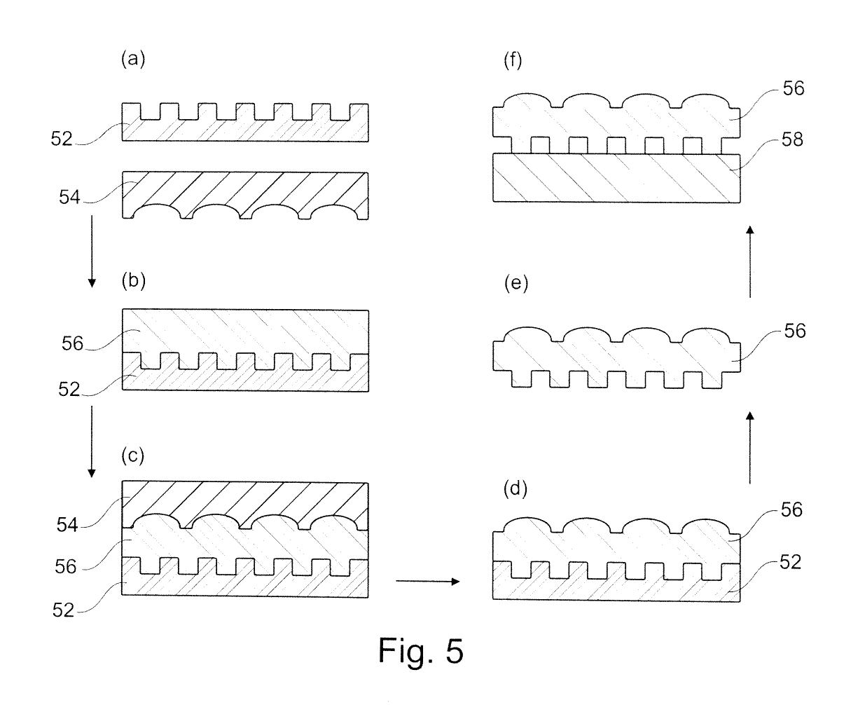

FIG. 5 shows a method of forming a top-emitting organic light emitting device in accordance with an embodiment of the present invention. The method steps may be summarized as follows:

(a) Master Fabrication—Two structured masters 52, 54 are prepared by, for example, low cost technique such as micro-embossing, optical interference lithography etc. The master 52 is for the diffraction grating optical structure and is rigid (e.g. glass, silicon, etc.). The master 54 is for the microlens array and is flexible (e.g. a plastic sheet).

(b) Diffraction Grating Formation—A thermal or UV curable elastomeric material 56 (e.g. a PDMS (polydimethylsiloxane)) is cast on the master 52.

(c) Microlens Array Formation—Master 54 is laminated on the elastomeric material 56 and a thermal or UV cure is applied. For UV curing at least one of the masters must be UV transparent.

(d) Master 54 is peeled off.

(e) Elastomeric material 56 is peeled off to provide the double side structured encapsulant film comprising a diffraction grating on a lower side thereof and a microlens array on an upper side thereof.

(f) Finally, the encapsulant film is attached on top of a light emitting device 58 by self-adhesion or through an adhesive layer.

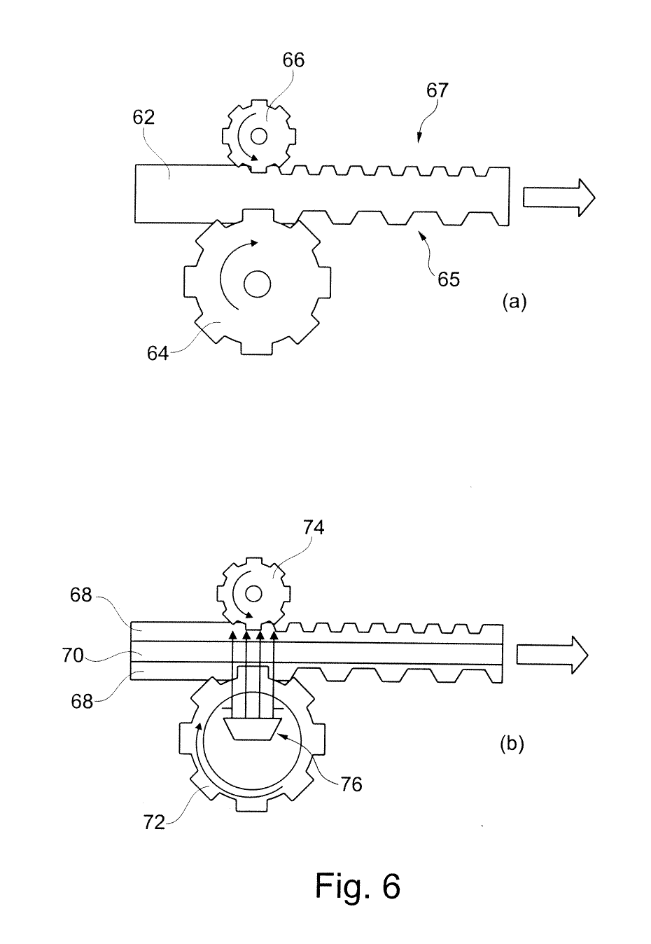

For mass production a roll to roll process can be applied. FIG. 6 shows such a process for different types of film materials. In FIG. 6(a) a plastic film 62 is thermally embossed by two structured rollers 64, 66. The roller 64 is patterned for forming a microlens array 65. The roller 66 is patterned for forming a diffraction grating structure 67. The plastic film is heated to an embossing temperature which preferably lies between the glass transition temperature and the melting point of the plastic film. At such temperatures the plastic film is soft enough to be embossed while the structural profile is retained after embossing.

FIG. 6(b) shows a similar roll to roll process as that shown in FIG. 6(a), the difference being the use of a plastic film coated with a precursor material for forming the microlens array and diffraction grating. For example, a UV curable liquid material 68 (with high viscosity) can be coated on both sides of a highly transparent plastic film 70. While the film is being embossed in between two structured rollers 72, 74 a UV cure is applied using a UV source 76 to solidify the structured liquid material. For UV curing at least one of the rollers may be UV transparent.

Embodiments of the present invention provide a technique of increasing light out-coupling efficiency that is based on integration of microlens arrays and photonic crystals (diffraction grating). Microlens arrays and diffraction gratings can be formed simultaneously in one step, such as embossing or moulding. A double-side structured encapsulant film is formed which can have various thicknesses from 1 μm to several millimetres depending on the application. For display applications a thin film with thickness ranging from 1 μm to 100 μm (less than the pixel size) is preferred. The structured optical film is laminated onto prefabricated optical devices such as organic electroluminescent devices.

Further features of organic electroluminescent devices according to embodiments of the present invention and their method of manufacture are discussed below.

### General Device Architecture

The architecture of the electroluminescent device according to embodiments of the invention comprises a glass or plastic substrate, an anode and a cathode. An electroluminescent layer is provided between the anode and the cathode.

In embodiments of the invention, at least the top electrode is transparent in order that light may be absorbed (in the case of a photoresponsive device) or emitted (in the case of an emissive device).

### Charge Transport Layers

Further layers may be located between the anode and the cathode, such as charge transporting, charge injecting or charge blocking layers.

In particular, it is desirable to provide a conductive hole injection layer, which may be formed from a conductive organic or inorganic material provided between the anode and the electroluminescent layer to assist hole injection from the anode into the layer or layers of semiconducting polymer. Examples of doped organic hole injection materials include doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and poly(thienothiophene). Examples of conductive inorganic materials include transition metal oxides such as VOx MoOx and RuOx as disclosed in Journal of Physics D: Applied Physics (1996), 29(11), 2750-2753.

If present, a hole transporting layer located between the anode and the electroluminescent layer preferably has a HOMO level of less than or equal to 5.5 eV, more preferably around 4.8-5.5 eV. HOMO levels may be measured by cyclic voltammetry, for example.

If present, an electron transporting layer located between electroluminescent layer and the cathode preferably has a LUMO level of around 3-3.5 eV.

### Electroluminescent Layer

The electroluminescent layer may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

The electroluminescent layer may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in the electroluminescent layer include small molecule, polymeric and dendrimeric materials, and compositions thereof. Suitable electroluminescent polymers for use in the electroluminescent layer include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers for use in the electroluminescent layer include electroluminescent metal complexes bearing dendrimeric groups as disclosed in, for example, WO 02/066552.

### Cathode

The cathode is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

If the cathode is the top electrode then in accordance with the present invention it is transparent. Transparent cathodes are particularly advantageous for active matrix devices because emission through a transparent anode in such devices is at least partially blocked by drive circuitry located underneath the emissive pixels. A transparent cathode will comprise a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Substrate and Encapsulation

Optical devices tend to be sensitive to moisture and oxygen. Accordingly, the substrate preferably has good barrier properties for prevention of ingress of moisture and oxygen into the device. The substrate is commonly glass. However, alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is encapsulated with an encapsulant to prevent ingress of moisture and oxygen. A getter material for absorption of any atmospheric moisture and/or oxygen that may permeate through the substrate or encapsulant may be provided.

### Other

In the previously described embodiments, the device is formed by firstly forming an anode on a substrate followed by deposition of an electroluminescent layer and a cathode. However, it will be appreciated that the device of the invention could also be formed by firstly forming a cathode on a substrate followed by deposition of an electroluminescent layer and an anode.

### Solution Processing

A single polymer or a plurality of polymers may be deposited from solution to form the organic layer(s) of the device. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. Inkjet printing of OLEDs is described in, for example, EP 0880303.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

While this invention has been particularly shown and described with reference to preferred embodiments thereof, it will be understood by those skilled in the art that various changes in form and details may be made therein without departing from the scope of the invention as defined by the appended claims.

1. An organic electroluminescent device comprising:
a substrate;
a first electrode disposed over the substrate for injecting charge of a first polarity;
a second electrode disposed over the first electrode for injecting charge of a second polarity opposite to said first polarity;
an organic light emitting layer disposed between the first and the second electrodes, the second electrode being adapted to allow light emitted by the light emitting layer to be transmitted through it; and
a transparent encapsulant disposed over the second electrode, wherein the transparent encapsulant comprises a microlens array formed by a top surface of the transparent encapsulant and a diffraction grating formed by a bottom surface of the transparent encapsulant.

2. An organic electroluminescent device as claimed in claim 1, wherein the transparent encapsulant comprises a single layer of material in which the microlens array and diffraction grating are disposed.

3. An organic electroluminescent device as claimed in claim 2, wherein the single layer of material is formed of a thermal cured or UV cured elastomeric material.

4. An organic electroluminescent device as claimed in claim 1, wherein the transparent encapsulant comprises a core layer and a coating layer on either side of the core layer in which the microlens array and the diffraction grating are disposed.

5. An organic electroluminescent device according to claim 1, wherein the transparent encapsulant comprises an optical coating over one or both of the microlens array and the diffraction grating.

6. An organic electroluminescent device according to claim 5, wherein the optical coating comprises an inorganic material.

7. An organic electroluminescent device according to claim 1, wherein the transparent encapsulant is disposed directly on the second electrode or directly on a thin film encapsulant disposed over the second electrode.

8. An organic electroluminescent device according to claim 7, wherein a transparent encapsulating can is disposed over the transparent encapsulant.

9. A method of manufacturing an organic electroluminescent device according claim 1, the method comprising:
depositing a first electrode over a substrate for injecting a charge of a first polarity;
depositing an organic light emitting layer over the first electrode;
depositing a second electrode over the organic light emitting layer for injecting charge of a second polarity opposite to said first polarity, the second electrode being being adapted to allow light emitted by the light emitting layer to be transmitted through it; and
providing a transparent encapsulant over the second electrode, wherein the transparent encapsulant comprises a microlens array formed by a top surface of the transparent encapsulant and a diffraction grating formed by a bottom surface of the transparent encapsulant.

10. A method as claimed in claim 9, comprising forming the microlens array and the optical structure in the transparent encapsulant prior to disposing the thin film encapsulant over the second electrode.

11. A method as claimed in claim 9, comprising forming the microlens array and the optical structure by embossing, printing, etching, photolithographic patterning, or roll-to-roll processing.

12. A method as claimed in claim 9, comprising forming the microlens array and the diffraction grating by embossing and softening the transparent encapsulant by heating by applying a solvent prior to embossing.

13. A method as claimed in claim 9, comprising depositing a precursor material as a coating on the transparent encapsulant film prior to embossing and embossing the coating prior to curing of the precursor material.

14. A method as claimed in claim 9, comprising forming the microlens array and the diffraction grating by embossing using a pair of rollers facing one another, each roller having a patterned surface corresponding respectively to the microlens array and the diffraction grating, the transparent encapsulant being passed between the rollers which contact opposing sides of the encapsulant film to form the microlens array and the optical structure.

15. A transparent encapsulant film for an organic electroluminescent device, comprising a microlens array formed in one surface of the transparent encapsulant film and a diffraction grating formed in the other surface of the transparent encapsulant film.

16. A transparent encapsulant film as claimed in claim 15, wherein the transparent encapsulant film comprises a single layer of material in which the microlens array and diffraction grating are disposed.

17. A transparent encapsulant film according to claim 16, wherein the single layer of material is formed of a thermal cured or UV cured elastomeric material.

18. A transparent encapsulant film as claimed in claim 15, wherein the transparent encapsulant comprises a core layer and a coating layer on either side of the core layer in which the microlens array and the diffraction grating are disposed.

19. A method of forming a transparent encapsulant film as claimed in claim 15, the method comprising forming a microlens array in one surface of the transparent encapsulant film and forming a diffraction grating in the other surface of the transparent encapsulant film.

20. A method as claimed in claim 19, comprising forming the microlens array and the optical structure by embossing, printing, etching, photolithographic patterning, or roll-to-roll processing.

21. A method as claimed in claim 19, comprising forming the microlens array and the diffraction grating by embossing using a pair of rollers facing one another, each roller having a patterned surface corresponding respectively to the microlens array and the optical structure, the transparent encapsulant film being passed between the rollers which contact opposing sides of the encapsulant film to form the microlens array and the diffraction grating.
